(19) United States
(12) Patent Application Publication
(10) Pub. No.: US 2007/0280016 A1
(43) Pub. Date: Dec. 6, 2007

(54) SEMICONDUCTOR DEVICE AND METHOD FOR OPERATING A SEMICONDUCTOR DEVICE

(75) Inventor: Thorsten Bucksch, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Munchen (DE)

(21) Appl. No.: 11/743,782

(22) Filed: May 3, 2007

(30) Foreign Application Priority Data
May 5, 2006 (DE) 10 2006 021 043.3

(51) Int. Cl. G11C 7/00

(52) U.S. Cl. 365/201

(57) ABSTRACT

One aspect relates to a semiconductor device, and to a method for operating a semiconductor device. In one case, the method includes incorporating the semiconductor device in an electronic module, and programming at least one eFuse provided on the semiconductor device after the incorporation of the semiconductor device in the electronic module.

### CROSS-REFERENCE TO RELATED APPLICATIONS

This Utility Patent Application claims priority to German Patent Application No. DE 10 2006 021043.3 filed on May 5, 2006, which is incorporated herein by reference.

### BACKGROUND

The invention relates to a semiconductor device, in particular to a buffer device, and to a method for operating a semiconductor device.

Semiconductor devices, e.g., corresponding, integrated (analog or digital) computing circuits, semiconductor memory devices such as functional memory devices (PLAs, PALs, etc.) and table memory devices (e.g., ROMs or RAMs, in particular SRAMs and DRAMs), data buffer devices, etc., etc. are subject to comprehensive tests in the course of their manufacturing process.

For the common manufacturing of a plurality of (in general identical) semiconductor devices, a wafer (i.e. a thin disc consisting of monocrystalline silicon) is used. The wafer is processed appropriately (e.g., successively subject to a plurality of coating, exposure, etching, diffusion, and implantation process steps, etc.), and subsequently e.g., sawn apart (or e.g., scratched and broken), so that the individual devices are then available.

During the manufacturing of semiconductor devices (e.g., of DRAMS (Dynamic Random Access Memories or dynamic write-read memories, respectively), data buffer devices, etc.), the (semi-finished) devices (that are still positioned on the wafer) may—even before all the desired, above-mentioned processing steps were performed at the wafer—(i.e. already in a semi-finished state of the semiconductor devices) be subject to appropriate test methods (e.g., kerf measurements at the wafer kerf) at one or a plurality of test stations by using one or a plurality of test devices.

After the finishing of the semiconductor devices (i.e. after the performing of all the above-mentioned wafer processing steps), the semiconductor devices are subject to further test methods at one or a plurality of (further) test stations—the finished devices that are still positioned on the wafer may, for instance, be correspondingly tested by using appropriate (further) test devices (“disc tests”).

Correspondingly, one or a plurality of further tests may be performed (at appropriate further test stations, using appropriate, further test devices) e.g., after the incorporation of the semiconductor devices in the corresponding semiconductor device packages, and/or e.g., after the incorporation of the semiconductor device packages (along with the respective semiconductor devices incorporated therein) in corresponding electronic modules (“module tests”).

By using the above-mentioned test methods it is possible to identify and then sort out (or partially also repair) defective semiconductor devices or modules, respectively, and/or—corresponding to the test results achieved—to correspondingly modify or optimally adjust, respectively, the process parameters used during the manufacturing of the devices.

Alternatively or additionally—corresponding to the test results achieved—a respective optimum adjustment of the devices may be performed flexibly, e.g., with regard to calibration, timing, etc.

To this end, specific electric fuses, or eFuses, may be provided on the devices, which—depending on the test results achieved—are either left in an unprogrammed state, or are programmed, i.e. fused by using a fuse voltage supplied via a fuse voltage pin.

For performing the above-mentioned test methods, and/or for adjusting a semiconductor device, in particular for programming the above-mentioned eFuses, the corresponding device may include a JTAG module (JTAG=Joint Test Action Group) defined in IEEE Standard 1149.

In accordance with the above-mentioned standard, a JTAG module—provided on the corresponding semiconductor device—includes a test access port (TAP) that is connected with four or—optionally—five test pins by using which a test clock signal TCK (TCK=Test Clock), a test mode select signal TMS (TMS=Test Mode Select), a data input signal TDI (TDI=Test Data In), a data output signal TDO (TDO=Test Data Out), and—optionally—a test reset signal TRST (TRST=Test Reset) can be input in/output from the device to be tested or to be adjusted.

In a plurality of applications—e.g., with server or work station computers, etc., etc.—memory modules with upstream data buffer devices, e.g., “buffered DIMMs”, may be used.

Such memory modules include in general one or a plurality of semiconductor devices, in particular DRAMs (e.g., DDR-DRAMs) and one or a plurality of data buffer devices—upstream of the semiconductor devices—(e.g., appropriate DDR-DRAM data buffer devices standardized by Jedec).

The data buffer devices may, for instance, be arranged on the same printed circuit board as the DRAMs.

The memory modules are—in particular by interconnection of an appropriate memory controller (that is, for instance, arranged externally of the respective memory module)—connected with one or a plurality of micro processors of the respective server or work station computer, etc.

In the case of “partially” buffered memory modules, the address and control signals—that are, for instance, output by the memory controller or by the respective processor—may be (shortly) buffered by appropriate data buffer devices, and correspondingly similar address and control signals may—in a time coordinated, possibly multiplexed or demultiplexed manner—be transmitted to the memory devices, e.g., DRAMs.

The (payload) data signals—output by the memory controller or by the respective processor, respectively—may be transmitted directly, i.e. without being buffered by an appropriate data buffer device, to the memory devices (and—vice versa—also the (payload) data signals output by the memory devices may be transmitted directly—without the interconnection of an appropriate data buffer device—to the memory controller or the respective processor, respectively).

In the case of fully buffered memory modules, both the address and control signals exchanged between the memory controller or the respective processor, respectively, and the memory devices, and the corresponding (payload) data signals are buffered by appropriate data buffer devices and only then transmitted to the memory devices or the memory controller or the respective processor.

In particular with memory modules destined for server or work stations may the exchange of the (payload) data and/or address and/or control signals between the memory controller or processor, respectively, and the respective data buffer device be performed via a high speed multiplex data connection permitting relatively high data rates (e.g., up to 4.8 Gbit/s), wherein the output data are each correspondingly multiplexed by the respective sender (e.g., by the processor or controller (or by the data buffer device)), and the received data are each correspondingly demultiplexed by the respective receiver (e.g., by the data buffer device (or by the processor or controller)).

The exchange of (payload) data and/or address and/or control signals between the respective data buffer device and the memory devices provided on the respective module may then be performed at a correspondingly lower data rate than with the above-mentioned high speed data connection provided between the controller or processor, respectively, and corresponding data buffer devices (e.g., only with 0.1 to 2 Gbit/s).

It is of disadvantage that, after the incorporation of a data buffer device in a memory module, a JTAG test access port (TAP) provided on the data buffer device, or the corresponding JTAG pins, respectively, are not longer accessible (and neither is the above-mentioned fuse voltage pin).

eFuses that are addressable via the JTAG access port can thus no longer be programmed after the incorporation of the data buffer device in the memory module, i.e. the calibration, the timing, etc. of the data buffer device can no longer be adapted after the incorporation of the data buffer device in the memory module.

For these and other reasons there is a need for the present invention.

### SUMMARY

One embodiment is a semiconductor device and another is a method for operating a semiconductor device. In one case, the method includes incorporating the semiconductor device in an electronic module, and programming at least one eFuse provided on the semiconductor device after the incorporation of the semiconductor device in the electronic module.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 a schematic representation of a fully buffered memory module with corresponding memory devices and a data buffer device in accordance with an embodiment of the invention.

FIG. 2 a schematic representation of a plurality of memory modules that are connected to a controller or a processor, respectively.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is an embodiment of the invention to provide a novel semiconductor device, in particular a buffer device, and a novel method for operating a semiconductor device, in particular a device and a method in which a corresponding adjustment of the device can be performed even after the incorporation of the device in a module.

In accordance with one embodiment of the invention there is provided a method for operating a semiconductor device, in particular a buffer device, which includes the processes of:
incorporating the semiconductor device in an electronic module, and
programming at least one eFuse provided on the semiconductor device after the incorporation of the semiconductor device in the electronic module.

In accordance with a further embodiment of the invention there is provided a semiconductor device, in particular a buffer device, including at least one eFuse that is adapted to be programmed after the incorporation of the semiconductor device in an electronic module.

The semiconductor device includes a control register for controlling the programming of the at least one eFuse.

In one embodiment of the invention, the semiconductor device further includes a serial or quasi-serial bus interface, in particular a SMBus interface, wherein data can be written in the control register (103) and/or data can be read out from the control register (103) via the interface.

Thus, the eFuse can be programmed even after the incorporation of the device in the module and an appropriate adjustment of the device can be performed.

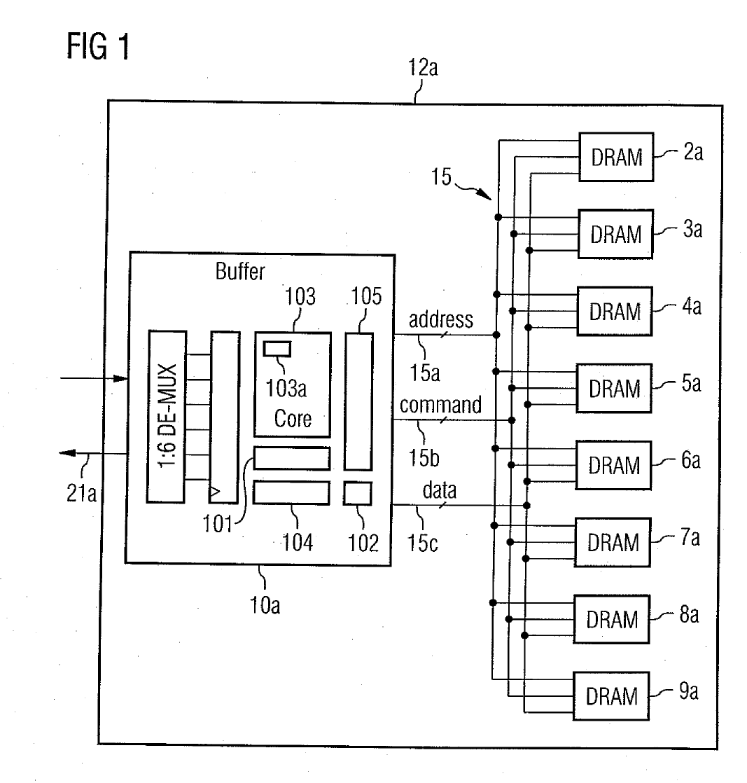

FIG. 1 illustrates a schematic representation of a fully buffered memory module 12a (here: a fully buffered DIMM or FBDIMM 12a).

It includes a plurality of memory devices 2a, 3a, 4a, 5a, 6a, 7a, 8a, 9a and a data buffer device (buffer) 10a upstream of the memory devices 2a, 3a, 4a, 5a, 6a, 7a, 8a, 9a.

The memory devices 2a, 3a, 4a, 5a, 6a, 7a, 8a, 9a may, for instance, be functional memory devices (PLAs, PALs, etc.) or table memory devices (.g. ROMs or RAMs), in particular SRAMs or DRAMs, in particular DDR (Double Date Rate) DRAMs, and the data buffer device (buffer) 10a may, for instance, be an AMB or Advanced Memory Buffer device 10a.

As results from FIG. 1, the memory devices 2a, 3a, 4a, 5a, 6a, 7a, 8a, 9a are arranged on the same printed circuit board as the buffer 10a.

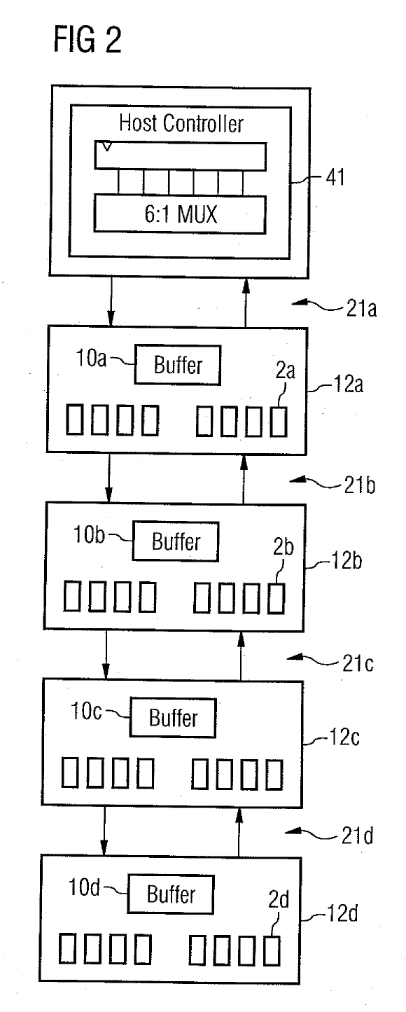

As will be explained in more detail in the following, the memory module 12a or the memory module printed circuit board (and—as is illustrated in FIG. 2—a plurality of further memory modules 12b, 12c, 12d or memory module printed circuit boards, respectively) may, by interconnection of an appropriate memory controller 41 (which is, for instance, arranged externally of the memory modules 12a, 12b, 12c, 12d or the corresponding printed circuit boards, respectively), be electrically connected with one or a plurality of micro processors, in particular with one or a plurality of microprocessors of a server or work station computer—provided on one or a plurality of further printed circuit boards, in particular a motherboard—(or with any other microprocessor, e.g., of a PC, laptop, etc.).

The memory module 12 (or the memory module printed circuit board, respectively) illustrated in FIG. 1—and also the memory modules 12a, 12b, 12c, 12d or memory module printed circuit boards, respectively, illustrated in FIG. 2—may each be designed as plug-in card and be, for instance, plugged in the above-mentioned motherboard at appropriate slots.

As results from FIG. 1 and as will be explained in more detail in the following, corresponding (payload) data, control and address signals originating, for instance, from the memory controller or from the respective processor and transmitted, for instance, via a corresponding high speed multiplex data bus 21a (in particular a corresponding, first channel (“south bound channel”) may be—shortly—buffered in the buffer 10a of the memory module 12a and be transmitted—in a time coordinated and demultiplexed manner—to the memory devices 2a, 3a, 4a, 5a, 6a, 7a, 8a, 9a provided on the memory module 12a (e.g., via corresponding data, control or address busses 15a, 15b, 15c (that are connected to a central bus 15)).

Vice versa, also the data, control or address signals output by the memory devices 2a, 3a, 4a, 5a, 6a, 7a, 8a, 9a, for instance, at the above-mentioned central bus 15 (in particular at the corresponding data, control or address bus 15a, 15b, 15c) may be—shortly—buffered in the buffer 10a and be transmitted to the memory controller or the respective processor, respectively, in a time coordinated and multiplexed manner (e.g.,—also—via the above-mentioned high speed multiplex data bus 21a, in particular an appropriate, further channel (i.e. a return channel (here: “north bound channel”))).

The exchange of the (payload) data and/or address and/or control signals between the memory controller 41 or processor, respectively, and the buffer 10a via the above-mentioned high speed multiplex data bus 21a may be performed at a relatively high data rate (e.g., between 2 and 10 Gbit/s, in particular e.g., with up to 4.8 Gbit/s), wherein the output data are each correspondingly multiplexed (e.g., subject to a 6:1 multiplex) by the respective sender (e.g., by the processor or controller 41 (or by the buffer 10a)), and the received data are each correspondingly demultiplexed (e.g., subject to a 1:6 demultiplex) by the respective receiver (e.g., the buffer 10a (or the processor or controller 41)).

The exchange of (payload) data and/or address and/or control signals between the buffer 10a and the memory devices 2a, 3a, 4a, 5a, 6a, 7a, 8a, 9a provided on the memory module 12a (via the above-mentioned central bus 15 or the corresponding data, control, or address busses 15a, 15b, 15c) may then be performed at a correspondingly lower data rate than with the above-mentioned high speed data connection provided between the controller 41 or processor, respectively, and the buffer 10a (e.g., only with between 0.1 and 2 Gbit/s, etc.).

As results from FIG. 2, the exchange of (payload) data and/or address and/or control signals between the individual memory modules (e.g., between the memory module 12a and the memory module 12b, etc.)—or more exactly: between the respective buffers of the memory modules (e.g., between the buffer 10a of the memory module 12a and the buffer 10b of the memory module 12b)—is performed in a correspondingly similar manner as between the memory controller 41 or processor, respectively, and the buffer 10a of the memory module 12a via corresponding high speed multiplex data busses 21b, 21c, 21d (or more exactly: via a respective corresponding bidirectional channel).

The exchange of the (payload) data and/or address and/or control signals between the different memory module buffers (e.g., between the buffer 10a of the memory module 12a and the buffer 10b of the memory module 12b, etc.) may—correspondingly as described above for the bus 21a—be performed at a relatively high data rate (e.g., between 2 and 10 Gbit/s, in particular e.g., with up to 4.8 Gbit/s), wherein the output data are each correspondingly multiplexed (e.g., subject to a 6:1 multiplex) by the respective sender (i.e. by the buffer outputting the respective data), and the received data are each correspondingly demultiplexed (e.g., subject to a 1:6 demultiplex) by the respective receiver (i.e. by the buffer receiving the respective data).

The different memory modules 12a, 12b, 12c, 12d (or the corresponding buffers 10a, 10b, 10c, 10d provided there) operate according to a “daisy chain” principle.

The signals sent by the memory controller 41 or the corresponding processor, respectively—via the bus 21a—to the first link of the “daisy chain” (here e.g., the memory module 12a) contain data characterizing the respectively addressed memory module (memory module 12a, 12b, 12c, 12d, etc.).

The buffer 10a of the memory module 12a (i.e. of the first link of the “daisy chain” transmits the data, address and control signals received—via the bus 21a—from the memory controller 41 or the corresponding processor, respectively, (possibly after a corresponding intermediate amplification) via the bus 21b to the second link of the “daisy chain” (here: the buffer 10b of the memory module 12b) (from where the data, address and control signals are (possibly after an appropriate intermediate amplification) transmitted to the third link of the “daisy chain”, etc., etc.)

Every buffer 10a, 10b knows its position in the chain. Which of the memory modules 12a, 12b is being addressed may be detected in the respective buffer 10a, 10b, e.g., by comparing the received memory module identification data with identification data (“ID number”) stored there—and individually identifying the respective buffer.

Due to time constraints, the transmission of the data, address and control signals between the individual memory modules (or buffers, respectively) is performed as a function of which of the memory modules 12a, 12b, etc. is actually addressed in the respective case (i.e. as a function of the memory module identification data contained in the respective signals).

The corresponding data, address, and control signals are, however—in a time coordinated and demultiplexed manner—transmitted to the memory devices provided on the respectively addressed memory module 12a, 12b only by the buffer 10a, 10b of the respective actually addressed memory module 12a, 12b (which is correspondingly identified by the identification data) (not, however, by the buffers of the remaining—not addressed—memory modules).

Correspondingly conversely as described above, the data, address, and control signals sent via a corresponding bus 21d in return direction (“north bound” direction) are also transmitted by the respectively receiving buffer (possibly after an appropriate intermediate amplification) to the respective preceding buffer (or memory controller, respectively) in the daisy chain (from where the data, address, and control signals are (possibly after an appropriate intermediate amplification) transmitted to the buffer that is even further ahead in the daisy chain, etc., etc.).

For adjustment of the buffers 10a, 10b, 10c, 10d (e.g., with respect to calibration, timing, the intensity of the respective voltages to be used by the buffer 10a, 10b, 10c, 10d, the respective functions to be provided by the buffer 10a, 10b, 10c, 10d, etc., etc.), a plurality of specific electric fuses, eFuses, are provided on the buffers 10a, 10b, 10c, 10d. These are—as is indicated in FIG. 1—arranged in one or a plurality of eFuse banks 101 provided on the buffers 10a, 10b, 10c, 10d.

Prior and/or after the incorporation of the buffers 10a, 10b, 10c, 10d in the memory modules 12a, 12b, 12c, 12d (more exactly: the producing of corresponding solder connections between the buffers 10a, 10b, 10c, 10d and the memory modules 12a, 12b, 12c, 12d or memory module printed circuit boards, respectively), the buffers 10a, 10b, 10c, 10d may be subject to a plurality of conventional test methods.

The eFuses provided on the buffers 10a, 10b, 10c, 10d may—e.g., depending on the test results achieved during the test methods—each either be left in an unprogrammed state or be programmed, i.e. fused.

In order to perform corresponding test methods prior to the incorporation of the buffers 10a, 10b, 10c, 10d in the memory modules 12a, 12b, 12c, 12d (and/or possibly for programming e.g., at least part of the above-mentioned eFuses), the buffers 10a, 10b, 10c, 10d may each include a JTAG module (JTAG=Joint Test Action Group) defined in IEEE Standard 1149.

According to the above-mentioned (JTAG-)Standard IEEE 1149, the JTAG module provided on the buffers 10a, 10b, 10c, 10d may each include a JTAG test access port (TAP) with which—prior to the incorporation of the buffers 10a, 10b, 10c, 10d in the memory modules 12a, 12b, 12c, 12d—a test clock signal TCK (TCK=Test Clock), a test mode select signal TMS (TMS=Test Mode Select), a data input signal TDI (TDI=Test Data In), a data output signal TDO (TDO=Test Data Out), and—optionally—a test reset signal TRST (TRST=Test Reset) can—via corresponding test pins—be input in/output from the respective buffer 10a, 10b, 10c, 10d (whereby the corresponding buffer 10a, 10b, 10c, 10d may be tested and/or may be adjusted appropriately by programming the above-mentioned part of the eFuses).

For programming or fusing the respectively desired eFuses addressed by using JTAG or the above-mentioned JTAG test access port, a corresponding—relatively high—external fuse voltage applied to the buffer fuse voltage pin, e.g., a voltage between 3.3V and 4V, may be applied to the respective buffer 10a, 10b, 10c, 10d via a corresponding buffer fuse voltage pin.

After the incorporation of the buffers 10a, 10b, 10c, 10d in the memory modules 12a, 12b, 12c, 12d (more exactly: the producing of corresponding solder connections between the buffers 10a, 10b, 10c, 10d and the memory modules 12a, 12b, 12c, 12d), one or a plurality of the above-mentioned buffers 10a, 10b, 10c, 10d (or an entire respective memory module 12a (i.e. the corresponding buffer 10a together with the respective memory devices 2a, 3a, 4a, 5a, 6a, 7a, 8a, 9a), and/or a plurality of memory modules 12a, 12b, 12c—may be connected with each other, for instance, via the above-mentioned busses 21a, 21b, 21c, 21d, in particular high speed multiplex data busses—may simultaneously (possibly with a connected memory controller 41 or processor, respectively) be subject to a plurality of further test methods (i.e. corresponding module and/or (entire) system tests).

In the present embodiment—as will be explained in more detail in the following—corresponding adjustments of the buffers 10a, 10b, 10c, 10d (e.g., with respect to calibration, timing, the intensity of the respective voltages to be used by the buffer 10a, 10b, 10c, 10d, the respective functions to be provided by the buffer 10a, 10b, 10c, 10d, etc., etc.) may be performed even after the incorporation of the buffers 10a, 10b, 10c, 10d in the memory modules 12a, 12b, 12c, 12d (more exactly: the producing of corresponding solder connections between the buffers 10a, 10b, 10c, 10d and the memory modules 12a, 12b, 12c, 12d), e.g., depending on the results achieved during the above-mentioned further test methods, in particular module and/or (entire) system tests.

In so doing, in addition to the above-mentioned adjustments performed by using JTAG or JTAG test access port, corresponding further adjustments may be performed (and/or refined adjustments (i.e. corresponding fine adjustments) vis-à-vis the above-mentioned (coarse) adjustments performed by using JTAG or JTAG test access port)—although, after the incorporation of the buffers 10a, 10b, 10c, 10d in the memory modules 12a, 12b, 12c, 12d the JTAG test access ports (or the corresponding JTAG pins, respectively) provided on the buffers, and/or the above-mentioned fuse voltage pin are no longer accessible. Alternatively, an adjustment and/or testing of the buffers 10a, 10b, 10c, 10d by using JTAG or JTAG test access port may be waived altogether and a—sole—adjustment of the buffers 10a, 10b, 10c, 10d by using the method that will be explained in more detail in the following may be performed.

For adjusting the buffers 10a, 10b, 10c, 10d after the incorporation of the buffers 10a, 10b, 10c, 10d in the memory modules 12a, 12b, 12c, 12d, the same electric fuses (eFuses)—arranged in the above-mentioned eFuse banks 101 provided on the buffers 10a, 10b, 10c, 10d—may be used which are also—as described above—adapted to be addressed by using JTAG or JTAG test access port, respectively, and to be programmed.

Alternatively, one or a plurality of the eFuses provided in the eFuse banks 101 (and/or one or a plurality of further eFuses) may be addressed or programmed exclusively by using JTAG, not, however, by using the method that will be explained in more detail in the following, and/or one or a plurality of the eFuses provided in the eFuse banks 101 (and/or one or a plurality of further eFuses) exclusively by using the method that will be explained in more detail in the following, but not by using JTAG (such eFuses may, instead in the eFuse bank 101, also be arranged in one or a plurality of further eFuse banks provided separately from the eFuse bank 101).

For programming or fusing the eFuses after the incorporation of the buffers 10a, 10b, 10c, 10d in the memory modules 12a, 12b, 12c, 12d by using the method that will be explained in more detail in the following—since the above-mentioned fuse voltage pin is possibly no longer accessible after the incorporation of the buffers 10a, 10b, 10c, 10d—a voltage may be used which is generated internally by a corresponding separate charge pump 102 provided on the buffers 10a, 10b, 10c, 10d.

This voltage may be relatively high, e.g., range between 3.3V and 4V, and be obtained by the charge pump 102 from an internal, smaller voltage available on the buffers 10a, 10b, 10c, 10d and ranging e.g., between 1.5V and 1.8V (wherein the voltage Vint available internally on the buffers 10a, 10b, 10c, 10d may, for instance, be obtained from an external supply voltage that may range between 1.5V and 2.5V, i.e. is smaller than the above-mentioned fuse voltage applied at the fuse voltage pin for a programming of eFuses via JTAG, and may, for instance, be supplied via the above-mentioned bus 21a, 21b, 21c or via a separate pin that is accessible (even) after the incorporation of the buffers 10a, 10b, 10c, 10d in the memory modules 12a, 12b, 12c, 12d).

The controlling of the fusing or programming of the eFuses after the incorporation of the buffers 10a, 10b, 10c, 10d in the memory modules 12a, 12b, 12c, 12d may, in accordance with the method used in the present embodiment, for instance, be performed via the above-mentioned (quasi-serial) high speed multiplex data bus 21a, 21b, 21c, 21d (or via signals that are transmitted via pins of the respective buffers 10a, 10b, 10c, 10d which are connected with the bus 21a, 21b, 21c, 21d), and/or—particularly—via a (quasi-serial) SMBus provided on the memory modules 12a, 12b, 12c, 12d (or via signals transmitted via SMBus pins of the buffers 10a, 10b, 10c, 10d which are connected with the SMBus).

The SMBus (SMBus=System Management Bus) specified by the Company Intel™ includes relatively few, e.g., only two, lines, in particular one clock and one data line (and the buffers 10a, 10b, 10c, 10d e.g., each two SMBus pins connected with these lines).

The transmission of data via the SMBus may be performed at a relatively low data rate, e.g., at maximally 100 kbit/s.

For controlling the fusing or programming of the eFuses after the incorporation of the buffers 10a, 10b, 10c, 10d in the memory modules 12a, 12b, 12c, 12d, one or a plurality of specific fuse control registers 103 may be provided in the buffers 10a, 10b, 10c, 10d—in particular in core regions 103a (“cores”) of the buffers 10a, 10b, 10c, 10d (i.e. in regions performing the actual core function of the buffers, i.e. the buffering of the above-mentioned data, address, and control signals) (alternatively, registers that are, in the normal operation of the buffers 10a, 10b, 10c, 10d, used as registers for buffering the above-mentioned data, address, and control signals to be transmitted to the above-mentioned further memory modules or to the above-mentioned controller 41 or the memory devices 2a, 3a, 4a, 5a, 6a, 7a, 8a, 9a may also be used as fuse control registers).

The fuse control register 103 may include one or a plurality of data fields including one or a plurality of bits which are adapted to be written via the SMBus (and/or the above-mentioned high speed multiplex data bus 21a, 21b, 21c, 21d) (e.g., a field “FUSE ENABLE” including one bit, a field “FUSE DURATION” including a plurality of bits, a field “FUSE SELECT” including a plurality of bits, a field “FUSE DATA” including a plurality of bits (and possibly a field “FUSE PROGRAM START” including one bit), and/or one or a plurality of data fields including one or a plurality of bits which are adapted to be read out via the SMBus (and/or the above-mentioned high speed multiplex data bus 21a, 21b, 21c, 21d) (e.g., a field “FUSE ERR” including one bit (and possibly the above-mentioned field “FUSE PROGRAM START” including one bit), etc.).

At the beginning of an eFuse fusing or programming process, the corresponding buffer 10a, 10b, 10c, 10d may be taken from the above-mentioned normal operation to a (specific) fuse programming operation. To this end, for instance, a corresponding, specific command—interpreted as mode change signal—(or a corresponding pattern sequence) may be applied to the above-mentioned high speed multiplex data bus 21a, 21b, 21c, 21d and/or SMBus.

Subsequent data that are transmitted via the high speed multiplex data bus 21a, 21b, 21c, 21d and/or SMBus are then interpreted by the buffer 10a, 10b, 10c, 10d as data to be written in the above-mentioned fuse control register 103 (in particular the above-mentioned register fields “FUSE ENABLE”, “FUSE DURATION”, “FUSE SELECT”, and “FUSE DATA”).

Each of the eFuses addressable in the buffers 10a, 10b, 10c, 10d after the incorporation of the buffers 10a, 10b, 10c, 10d in the memory modules 12a, 12b, 12c, 12d may be assigned a digital identification that individually identifies a respective eFuse, e.g., an identification “000001” to a first one of the eFuses, an identification “000010” to a second one of the eFuses, an identification “000011” to a third one of the eFuses, etc.

By writing the identification assigned to the respective eFuse to be fused or programmed (or the corresponding data) in the “FUSE SELECT” field of the fuse control register 103 via the high speed multiplex data bus 21a, 21b, 21c, 21d and/or SMBus in the above-mentioned fuse programming operation, the eFuse defined by the respective identification may be selected for fusing or programming.

Furthermore, by writing corresponding data in the “FUSE DURATION” field of the fuse control register 103 via the high speed multiplex data bus 21a, 21b, 21c, 21d and/or SMBus in the above-mentioned fuse programming operation for the respective eFuse selected for fusing or programming, the duration of the respective fusing or programming process may be selected (i.e. it may be determined how long the above-mentioned voltage generated by the charge pump 102 is to be applied to the respective eFuse (or for how many clocks of a—relatively slow—clock signal generated by a separate fuse programming clock generator 104 provided on the buffer 10a, 10b, 10c, 10d)).

By writing corresponding data in the “FUSE ENABLE” field of the fuse control register 103 via the high speed multiplex data bus 21a, 21b, 21c, 21d and/or SMBus in the above-mentioned fuse programming operation it may be selected whether the respective eFuse is actually to be fused or programmed (e.g., by writing a “1” in the “FUSE ENABLE” field), or whether, instead of a “hard” fusing (i.e. a permanent programming) of the respective eFuse (“hardset”), the respective buffer 10a, 10b, 10c, 10d is merely to be placed temporarily (non-permanently) in an adjustment corresponding to an adjustment achieved during a hard fusing or programming of the respective eFuse—i.e. whether a “softset” is to be performed (e.g., by writing a “0” in the “FUSE ENABLE” field).

This way, the respective buffer 10a, 10b, 10c, 10d (or the memory module 12a altogether (i.e. the corresponding buffer 10a together with the respective memory devices 2a, 3a, 4a, 5a, 6a, 7a, 8a, 9a), and/or a plurality of memory modules 12a, 12b, 12c—which are, for instance, connected with each other via the above-mentioned busses 21a, 21b, 21c, 21d, in particular high speed multiplex data busses—can simultaneously (possibly with a connected memory controller 41 or processor, respectively)) be tested with the respective adjustment of the buffer 10a, 10b, 10c, 10d performed by using “softset”.

If the tests are successful, a “hardset” can subsequently be performed, i.e. the respective eFuse can be fused “hard” or be programmed permanently, respectively (e.g., by repetition of the above-mentioned process (or of the process explained in detail below) with a “1” identifying a “hardset” and written in the “FUSE ENABLE” field in the above-mentioned fuse programming operation via the high speed multiplex data bus 21a, 21b, 21c, 21d and/or SMBus).

If the tests are not successful, the respective buffer 10a, 10b, 10c, 10d may be returned to the original (default) adjustment—existing prior to the “softset”—, e.g., by performing a reset.

After, as explained above, the above-mentioned data have been written in the corresponding fields (“FUSE ENABLE”, “FUSE DURATION”, “FUSE SELECT”, etc.) of the fuse control register 103 in the above-mentioned fuse programming operation via the high speed multiplex data bus 21a, 21b, 21c, 21d and/or SMBus, the actual eFuse programming or fusing process is performed, controlled by a separate eFuse programming controller 105 provided on the respective buffer 10a, 10b, 10c, 10d:

The beginning of the (actual) programming or fusing process may be signalized from outside (i.e. via the high speed multiplex data bus 21a, 21b, 21c, 21d and/or SMBus), or alternatively by the eFuse programming controller 105, in particular by setting the bit in the above-mentioned “FUSE PROGRAM START” field of the fuse control register 103, e.g., by writing a “1” in the above-mentioned “FUSE PROGRAM START” field.

Next or in reaction thereto, the above-mentioned charge pump 102 is activated by the eFuse programming controller 105, and the voltage generated by the charge pump 102 is applied to the eFuse defined by the identification stored in the “FUSE SELECT” field of the fuse control register 103.

Furthermore—controlled by the eFuse programming controller 105—the above-mentioned fuse programming clock generator 104 is activated, so that it starts generating the above-mentioned—relatively slow—clock signal. Additionally—also controlled by the eFuse programming controller 105—a timer provided on the respective buffer 10a, 10b, 10c, 10d is started.

By using the timer it is determined when the fusing or programming duration indicated by the data stored in the “FUSE DURATION” field of the fuse control register 103 for the respective eFuse selected for fusing or programming has expired.

To this end, the timer or the eFuse programming controller 105 may compare the number of clocks generated since the beginning of the (actual) programming or fusing process or since the start of the timer, respectively, by the fuse programming clock generator 104 (or, for instance, the number of positive (or negative) clock edges) with the value stored in the “FUSE DURATION” field of the fuse control register 103.

If it is determined that the fuse or programming duration has expired, the eFuse programming controller 105 deactivates the above-mentioned charge pump 102, or the corresponding voltage generated by the charge pump 102 is no longer applied to the corresponding eFuse, respectively.

Furthermore—also controlled by the eFuse programming controller 105—the above-mentioned fuse programming clock generator 104 is deactivated (so that it does not generate any more clock signal), and the timer is stopped or reset, respectively.

Next, the eFuse programming controller 105 resets the above-mentioned bit in the “FUSE PROGRAM START” field of the fuse control register 103, e.g., by writing a “0” in the above-mentioned “FUSE PROGRAM START” field.

Alternatively, prior or after the resetting of the bit in the “FUSE PROGRAM START” field of the fuse control register 103, the eFuse programming controller 105 may examine whether the respective eFuse was fused or programmed successfully (e.g., in that the eFuse programming controller 105 initiates the applying of a corresponding read voltage to the respective eFuse and determines whether a current flows through the eFuse in reaction to the read voltage (programming not successful), or no current or only a current ranging below a predetermined threshold value (programming successful)).

If the programming was not successful, the eFuse programming controller 105 may set the above-mentioned bit in the “FUSE ERR” field of the fuse control register 103, e.g., by writing a “1” in the above-mentioned “FUSE ERR” field.

By reading out the bit in the above-mentioned “FUSE PROGRAM START” field of the fuse control register 103, and/or the bit in the above-mentioned “FUSE ERR” field of the fuse control register 103 via the high speed multiplex data bus 21a, 21b, 21c, 21d and/or SMBus in the above-mentioned fuse programming operation, it may be determined—from outside—whether the actual programming or fusing process was again terminated by the programming controller 105, and/or whether it was successful.

If not, a corresponding programming or fusing process may—possibly automatically—be initiated again—from outside—(i.e. via the high speed multiplex data bus 21a, 21b, 21c, 21d and/or SMBus) for the respective eFuse (i.e. the above-explained process may be repeated for the same eFuse).

The above-mentioned “FUSE PROGRAM START” field and/or “FUSE ERR” field may be read out via the high speed multiplex data bus 21a, 21b, 21c, 21d and/or SMBus e.g., periodically-regularly after respective predetermined periods (the performing of a new programming or fusing process may then be delayed until the previous programming or fusing process is terminated by the eFuse programming controller 105 and the bit was reset in the “FUSE PROGRAM START” field by the eFuse programming controller 105).

Alternatively, a new programming or fusing process may—from outside—(i.e. via the high speed multiplex data bus 21a, 21b, 21c, 21d, and/or SMBus) be initiated automatically a predetermined time after the beginning of the previous programming or fusing process (without previous reading out of the “FUSE PROGRAM START” bit).

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for operating a semiconductor device comprising:
incorporating the semiconductor device in an electronic module; and
programming at least one eFuse provided on the semiconductor device after the incorporation of the semiconductor device in the electronic module.

2. The method of claim 1, wherein the electronic module is a memory module.

3. The method of claim 1, further comprising soldering the semiconductor with the module on incorporation in the module.

4. The method of claim 1, wherein the semiconductor device is a buffer device.

5. The method of claim 4, wherein the buffer device is an AMB (Advanced Memory Buffer) device.

6. The method of claim 4, wherein the buffer device is incorporated in the electronic module together with at least one memory device.

7. The method of claim 1, further comprising controlling the programming of the at least one eFuse by using a control register provided on the semiconductor device.

8. The method of claim 7, wherein data are written in the control register via a serial or quasi-serial bus.

9. The method of claim 8, wherein data are read out from the control register via the serial or quasi-serial bus.

10. The method of claim 8, wherein the bus is a SMBus.

11. The method of claim 7, wherein a plurality of eFuses are provided on the semiconductor device, and wherein the respective eFuse to be programmed is selected by using the control register.

12. The method of claim 11, wherein the programming duration for the respective eFuse to be programmed is controlled by using the control register.

13. The method of claim 1, wherein a separate charge pump is provided on the semiconductor device for programming the at least one eFuse.

14. The method of claim 1, wherein a separate clock generator is provided on the semiconductor device for monitoring the programming duration during the programming of the at least one eFuse.

15. A semiconductor device comprising:
at least one eFuse;
wherein the eFuse is adapted to be programmed after the incorporation of the semiconductor device in an electronic module.

16. The semiconductor device of claim 15, further comprising a control register for controlling the programming of the at least one eFuse.

17. The semiconductor device of claim 16, comprising a serial or quasi-serial bus interface, in particular SMBus interface, wherein data can be written in the control register and/or data can be read out from the control register via the interface.

18. The semiconductor device of claim 15, wherein the semiconductor device is a buffer device.

19. The semiconductor device of claim 18, wherein the buffer device is an Advanced Memory Buffer.

20. The semiconductor device of claim 15, wherein the electronic module is a memory module.
